(19) United States
(12) Patent Application Publication
(10) Pub. No.: US 2019/0148908 A1
(43) Pub. Date: May 16, 2019

(54) OPTOELECTRONIC COMPONENT AND METHOD OF OPERATING AN OPTOELECTRONIC COMPONENT

(71) Applicant: OSRAM Opto Semiconductors GmbH, Regensburg (DE)

(72) Inventor: Hubert Halbritter, Dietfurt-Toeging (DE)

(21) Appl. No.: 16/085,618

(22) PCT Filed: Mar. 15, 2017
(86) PCT No.: PCT/EP2017/056094

§ 371 Date: Sep. 17, 2018

(30) Foreign Application Priority Data
Mar. 17, 2016 (DE) 10 2016 104 946.8

(51) Int. Cl. H01S 5/022; H01S 5/068; F21V 23/04; F21V 25/00

(52) U.S. Cl. CPC H01S 5/02296; H01S 5/02292; F21Y 2115/30; F21V 23/0457; F21V 25/00; H01S 5/06825

(57) ABSTRACT

An optoelectronic component includes a first optoelectronic semiconductor chip that emits useful light and extends in the optoelectronic component along a first light path, an optical element arranged in the first light path, a second optoelectronic semiconductor chip that emits test light and extends in the optoelectronic component along a second light path, wherein the optical element forms a part of the second light path, and a light detector that detects test light that has passed through the second light path.

### TECHNICAL FIELD

This disclosure relates to an optoelectronic component and a method of operating an optoelectronic component.

### BACKGROUND

Optoelectronic components are known, the design and usage of which has to preclude a hazard to persons, in particular a risk of damage to eyes. This is the case, for example, for semiconductor lasers of laser class 1. A known measure of enhancing the eye safety is the use of diffractive optical elements.

### SUMMARY

I provide an optoelectronic component including a first optoelectronic semiconductor chip that emits useful light and extends in the optoelectronic component along a first light path, an optical element arranged in the first light path, a second optoelectronic semiconductor chip that emits test light and extends in the optoelectronic component along a second light path, wherein the optical element forms a part of the second light path, and a light detector that detects test light that has passed through the second light path.

I also provide a method of operating an optoelectronic component including testing whether an established amount of test light emitted by a second optoelectronic semiconductor chip reaches a light detector along a second light path, of which an optical element forms a part; and emitting useful light along a first light path in which the optical element is arranged by a first optoelectronic semiconductor chip if the testing was successful.

### BRIEF DESCRIPTION OF THE DRAWINGS

FIG. 1 schematically shows a first optoelectronic component in a first operating state.

FIG. 2 schematically shows the first optoelectronic component in a second operating state.

FIG. 3 schematically shows a second optoelectronic component in a first operating state.

FIG. 4 schematically shows the second optoelectronic component in a second operating state.

List of Reference Numerals

| | |
|---|---|
| 10 | optoelectronic component |
| 20 | optoelectronic component |
| 100 | first optoelectronic semiconductor chip |
| 105 | useful light |
| 110 | first light path |
| 120 | mirror element |
| 200 | second optoelectronic semiconductor chip |
| 205 | test light |
| 210 | second light path |
| 220 | first deflection element |
| 230 | second deflection element |
| 300 | optical element |
| 400 | light detector |
| 500 | housing |
| 510 | first chamber |
| 520 | second chamber |
| 530 | third chamber |
| 540 | cover glass |

### DETAILED DESCRIPTION

My optoelectronic component comprises a first optoelectronic semiconductor chip that emits useful light, which extends in the optoelectronic component along a first light path, an optical element arranged in the first light path, a second optoelectronic semiconductor chip that emits test light, which extends in the optoelectronic component along a second light path, wherein the optical element forms a part of the second light path, and a light detector that detects test light that has passed through the second light path.

This optoelectronic component advantageously enables automatic recognition of damage or absence of the optical element. This enables automatic shutdown or prevention of a startup of the first optoelectronic semiconductor chip of the optoelectronic component in the case of damage or absence of the optical element. In this way, with this optoelectronic component only a small risk exists of a hazard to eye safety due to damage or absence of the optical element. The automatic recognition of damage or absence of the optical element advantageously takes place without electrical contacts arranged on the optical element, whereby no conductor tracks leading to the optical element are required in this optoelectronic component. The optical recognition of damage or absence of the optical element by the test light moreover advantageously enables even minor damage to the optical element to be detected.

The optical element may be a diffractive optical element. The optical element can advantageously reduce the intensity of the useful light sufficiently so that no hazard to eye safety exists.

The test light on the second light path may be conducted through the optical element. In the case of absence or damage of the optical element, the light guiding on the second light path is interrupted or restricted in this case, which can be automatically established.

The second light path in the optical element may extend perpendicularly to the first light path. This enables the second light path to be guided at greater length through the optical element, whereby damage can advantageously be recognized at different positions of the optical element.

The test light on the second light path may be deflected by the optical element. An absence of the optical element thus advantageously results in a particularly clear change of the path covered by the test light, which is simple to detect.

The test light on the second light path may be reflected externally at the optical element. This advantageously enables a simple design of the optoelectronic component.

The test light on the second light path may be reflected internally at the optical element. This advantageously enables the test light to be additionally guided through the optical element, whereby a particularly reliable recognition of damage or absence of the optical element can be enabled.

The test light on the second light path may be reflected multiple times at the optical element. Particularly reliable recognition of damage or absence of the optical element is advantageously also enabled in this way.

It may comprise a mirror element. In this case, the useful light on the first light path is deflected at the mirror element. The mirror element advantageously enables a compact and simple design of the optoelectronic component, in which the first optoelectronic semiconductor chip can be arranged and electrically contacted in a simple and space-saving manner in the optoelectronic component.

The first optoelectronic semiconductor chip may be a laser chip. The laser chip can in this case be, for example, an edge-emitting laser chip or a vertically emitting laser chip. In this optoelectronic component, eye safety is advantageously also ensured when the first optoelectronic semiconductor chip designed as a laser chip is operated at high power.

The second optoelectronic semiconductor chip may be a light-emitting diode chip. The second optoelectronic semiconductor chip is advantageously thus obtainable cost-effectively. A further advantage is that no risk to eye safety originates from the test light emitted by the second optoelectronic semiconductor chip.

The light detector may be a photodiode. The light detector thus advantageously enables simple and reliable detection of test light that has passed through the second light path.

A method of operating an optoelectronic component comprises steps of testing whether an established amount of test light emitted by a second optoelectronic semiconductor chip reaches a light detector along a second light path, of which an optical element forms a part, and emitting useful light along a first light path in which the optical element is arranged, by a first optoelectronic semiconductor chip, if the testing was successful.

In this method, advantageously, no useful light is emitted by the first optoelectronic semiconductor chip if the testing was not successful. It is thus ensured that useful light is only emitted if the optical element of the optoelectronic component is not damaged or absent. In this way, a hazard to a user of the optoelectronic component, in particular an eye hazard, can advantageously be precluded.

The testing may comprise a first measurement of a signal supplied by the light detector, while the second optoelectronic semiconductor chip does not emit test light, and a second measurement of a signal supplied by the light detector, while the second optoelectronic semiconductor chip emits test light. This enables the difference between the signal supplied by the light detector in the first measurement and the signal supplied by the light detector in the second measurement to be used to judge whether an established amount of the test light emitted by the second optoelectronic semiconductor chip reaches the light detector along the second light path. The subtraction enables in this case a background, for example, caused by ambient light, of the signals supplied by the light detector to be subtracted. The method thus advantageously has a particularly high accuracy and reliability.

The above-described properties, features, and advantages and the manner in which they are achieved will become clearly and evidently comprehensible in conjunction with the following description of the examples, which are explained in greater detail in conjunction with the drawings.

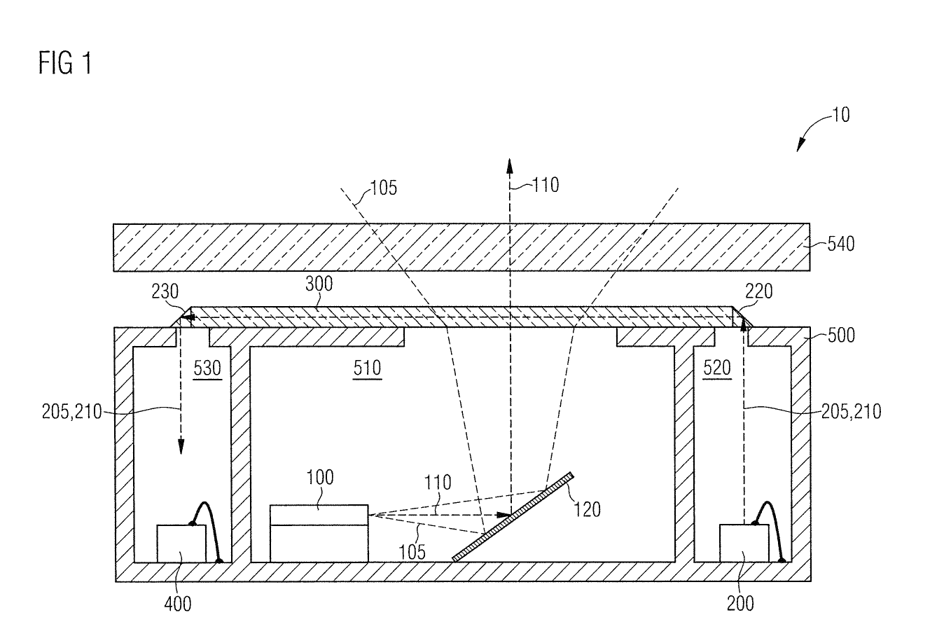

FIG. 1 shows a schematic sectional side view of an optoelectronic component 10 according to a first example. The optoelectronic component 10 is a laser component and provided for the purpose of emitting laser light. The optoelectronic component 10 can be used, for example, to generate a structured light pattern, for example, in a device for depth recognition. The optoelectronic component 10 can also be provided, for example, for distance measurement according to the runtime method (time-of-flight) or another purpose.

The optoelectronic component 10 comprises a housing 500. The housing 500 is divided into a first chamber 510, a second chamber 520, and a third chamber 530. However, this division of the housing 500 is merely by way of example. A division of the housing 500 into individual chambers 510, 520, 530 is not absolutely necessary. The housing 500 could also comprise additional further chambers.

A first optoelectronic semiconductor chip 100 is arranged in the first chamber 510 of the housing 500. The first optoelectronic semiconductor chip 100 is designed in the illustrated example as an edge-emitting laser chip. The first optoelectronic semiconductor chip 100 is designed for the purpose of emitting useful light 105 that is emitted outwardly by the optoelectronic component 10. The useful light 105 can be, for example, visible light or light having a wavelength from the infrared or ultraviolet spectral range.

The useful light 105 emitted by the first optoelectronic semiconductor chip 100 is deflected by 90° by a mirror element 120 arranged in the first chamber 510 of the housing 500 and exits from the optoelectronic component 10 through a cover glass 540 of the housing 500 of the optoelectronic component 10. In this case, the useful light 105 extends in the optoelectronic component 10 along a first light path 110. The useful light 105 passes through the cover glass 540 of the housing 500 substantially perpendicularly to the plane of the cover glass 540.

It is possible to arrange the first optoelectronic semiconductor chip 100 in an orientation other than that illustrated in the first chamber 510 of the housing 500 of the optoelectronic component 10 and, therefore the useful light 105 is deflected by an angle other than a right angle along the first light path 110 at the mirror element 120. It is also possible to arrange the first optoelectronic semiconductor chip 100 such that the useful light 105 is emitted by the first optoelectronic semiconductor chip 100 directly in the direction of the cover glass 540. In this case, the mirror element 120 can be omitted. It is also possible to provide more than one mirror element 120 and deflect the useful light 105 multiple times along the first light path 110.

The useful light 105 emitted by the first optoelectronic semiconductor chip 100 can have an intensity requiring measures to ensure the eye safety of a user of the optoelectronic component 10. For this purpose, an optical element 300 is arranged in the first light path 110 of the useful light 105 in the optoelectronic component 10. The optical element 300 is arranged between the first optoelectronic semiconductor chip 100 and the cover glass 540 of the housing 500 of the optoelectronic component 10 such that the useful light 105 on the first light path 110 passes through the optical element 300. The optical element 300 causes shaping, widening, or attenuation of the light beam of the useful light 105, which ensures eye safety.

The optical element 300 can be designed, for example, as a diffractive optical element or as an optical diffuser. An optical element 300 designed as a diffractive optical element can be used, for example, to generates a structured light pattern.

The optical element 300 is designed in the illustrated example as a small flat plate. The first light path 110 of the useful light 105 extends perpendicularly to the plane of the optical element 300 through the optical element 300.

In case of damage or removal of the optical element 300, useful light 105 emitted by the first optoelectronic semiconductor chip 100 of the optoelectronic component 10 could exit from the optoelectronic component 10 without previously having passed through the optical element 300. In this case, the eye safety of the optoelectronic component 10 would possibly no longer be ensured. Therefore, it has to be ensured in the optoelectronic component 10 that the first optoelectronic semiconductor chip 100 is not operated in the case of damage or absence of the optical element 300. For this purpose, it is necessary to automatically recognize damage or absence of the optical element 300.

The optoelectronic component 10 comprises a second optoelectronic semiconductor chip 200 arranged in the second chamber 520 of the housing 500. The second optoelectronic semiconductor chip 200 is designed for the purpose of emitting test light 205. The test light 205 can be, for example, visible light or light having a wavelength from the infrared or ultraviolet spectral range. Intensity and wavelength of the test light 205 are dimensioned such that the test light 205 does not represent a risk to a user of the optoelectronic component 10.

The second optoelectronic semiconductor chip 200 can be, for example, a light-emitting diode chip. The second optoelectronic semiconductor chip 200 could also be, however, a laser chip or another light-emitting optoelectronic semiconductor chip.

The test light 205 extends in the optoelectronic component 10 along a second light path 210. In this case, the optical element 300 forms a part of the second light path 210. The test light 205 arrives on the second light path 210 at a light detector 400 arranged in the third chamber 530 of the housing 500 of the optoelectronic component 10 and is designed for the purpose of detecting the test light 205 incident on the light detector 400. The light detector 400 can be, for example, a photodiode.

The test light 205 emitted by the second optoelectronic semiconductor chip 200 first arrives at a first deflection element 220 on the second light path 210. The first deflection element 220 deflects the test light 205 such that the further second light path 210 of the test light 205 extends through the optical element 300. In this case, the test light 205 is conducted parallel to the plane of the small plate-shaped optical element 300 through the optical element 300. The second light path 210 of the test light 205 therefore extends in the optical element 300 perpendicularly to the first light path 110 of the useful light 105.

After passing through the optical element 300, the test light 205 is incident on a second deflection element 230, which deflects it in the direction of the light detector 400. The further second light path 210 of the test light 205 then extends from the optical element 300 to the light detector 400.

The first deflection element 220 and the second deflection element 230 can each be, for example, mirror elements or prisms, which each deflect the test light 205 on the second light path 210 by 90°, for example. The first deflection element 220 and the second deflection element 230 could also be formed by parts of the optical element 300 itself, however, for example, by beveled lateral facets of the optical element 300, at which a deflection of the test light 205 takes place. In this case, the test light 205 is reflected twice internally at the optical element 300.

The region which the test light 205 passes through in the second chamber 520 of the housing 500 on the second light path 210 between the second optoelectronic semiconductor chip 200 and the first deflection element 220 can be filled with air or another gas. The region between the second optoelectronic semiconductor chip 200 and the first deflection element 220 can however also be filled, for example, with an epoxy or a silicone or can be a plastic waveguide to enhance the efficiency of the coupling of the test light 205 into the optical element 300. This also applies accordingly for the space through which the test light 205 passes on the second light path 210 in the third chamber 530 between the second deflection element 230 and the light detector 400, to enhance the efficiency of the decoupling of the test light 205 out of the optical element 300.

It is possible to arrange the second optoelectronic semiconductor chip 200 and the light detector 400 in the housing 500 of the optoelectronic component 10 such that no deflection of the test light 205 is necessary on the second light path 210 of the test light 205 between the second optoelectronic semiconductor chip 200 and the light detector 400. In this case, the first deflection element 220 and the second deflection element 230 can be omitted. In this case, the test light 205 passes linearly from the second optoelectronic semiconductor chip 200 into the optical element 300 and from the optical element 300 linearly to the light detector 400.

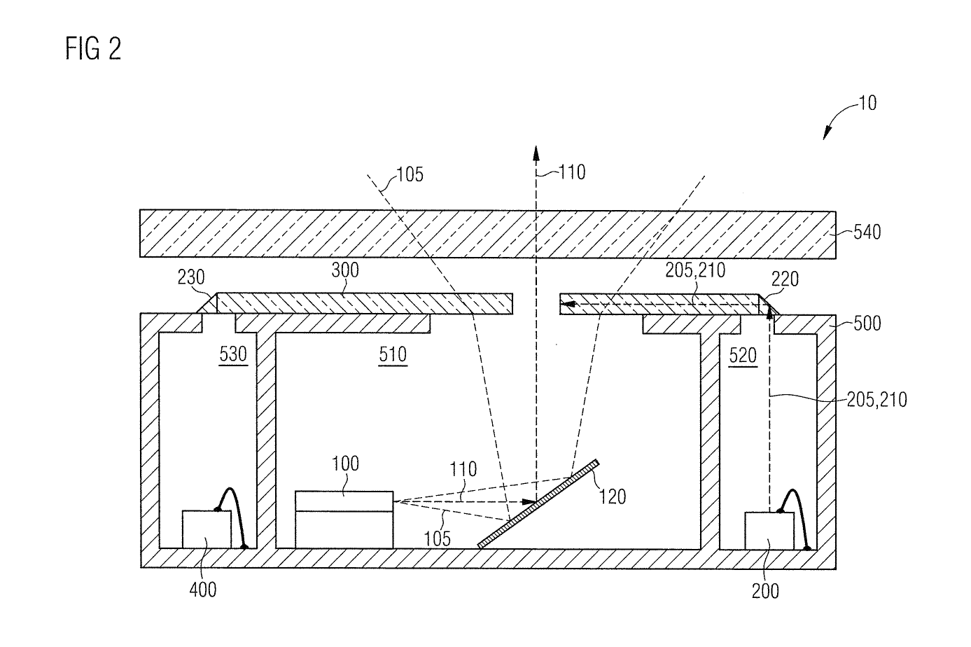

FIG. 2 shows a schematic sectional side view of the optoelectronic component 10 in a state in which the optical element 300 is damaged. If the first optoelectronic semiconductor chip 100 of the optoelectronic component 10 were operated in this state of the optoelectronic component 10, at least a part of the useful light 105 emitted by the first optoelectronic semiconductor chip 100 can exit through the cover glass 540 from the housing 500 of the optoelectronic component 10, without previously having passed through the optical element 300. The useful light 105 emitted by the optoelectronic component 10 can possibly endanger a user of the optoelectronic component 10 in this case. Therefore, the first optoelectronic semiconductor chip 100 cannot be operated in the state of the optoelectronic component 10 schematically shown in FIG. 2, in which the optical element 300 is damaged.

The test light 205 emitted by the second optoelectronic semiconductor chip 200 of the optoelectronic component 10 is coupled in the state of the optoelectronic component 10 shown in FIG. 2 on the second light path 210 by the first deflection element 200 into the optical element 300. However, the second light path 210 of the test light 205 is interrupted at the damage of the optical element 300. The test light 205 thus does not reach the second deflection element 230 and the light detector 400 or only reaches them in a reduced amount in the state of the optoelectronic component 10 shown in FIG. 2.

In the operating state of the optoelectronic component 10 shown in FIG. 2, the light detector 400 thus detects no test light 205 or at least an amount of the test light 205 reduced in relation to the state of the optoelectronic component 10 shown in FIG. 1. In this way, it can be established that the optical element 300 is absent or damaged. This enables activation electronics (not shown in schematic FIGS. 1 and 2) of the optoelectronic component 10 to turn off the first optoelectronic semiconductor chip 100 of the optoelectronic component 10 or not turn it on at all.

A method of operating the optoelectronic component 10 can provide, before the startup of the optoelectronic component 10, thus in particular before the startup of the first optoelectronic semiconductor chip 100, testing whether the optical element 300 is absent or damaged. For this purpose, first, the second optoelectronic semiconductor chip 200 is put into operation and tested as to whether an established minimum amount of the test light 205 emitted by the second optoelectronic semiconductor chip 200 reaches the light detector 400 along the second light path 210, of which the optical element 300 forms a part. The first optoelectronic semiconductor chip 100 is only put into operation in the next step if this is the case and, therefore, it emits useful light 105 along the first light path 110, in which the optical element 300 is arranged.

Particularly reliable recognition of damage or absence of the optical element 300 is enabled in that, first, in a first measurement, a signal supplied by the light detector 400 is recorded, while the second optoelectronic semiconductor chip 200 does not emit test light 205 and therefore test light 205 also cannot reach the light detector 400 and, subsequently, in a second measurement, a signal supplied by the light detector 400 is recorded, while the second optoelectronic semiconductor chip 200 emits test light 205 and this test light should thus reach the light detector 400 if the undamaged optical element 300 were present. The two measurements can alternately be carried out repeatedly during pulsed operation of the second optoelectronic semiconductor chip 200. A proportion of the signals supplied by the light detector 400 caused by ambient light incident on the light detector 400 can be subtracted by a comparison of the signals recorded during the first measurements and during the second measurements.

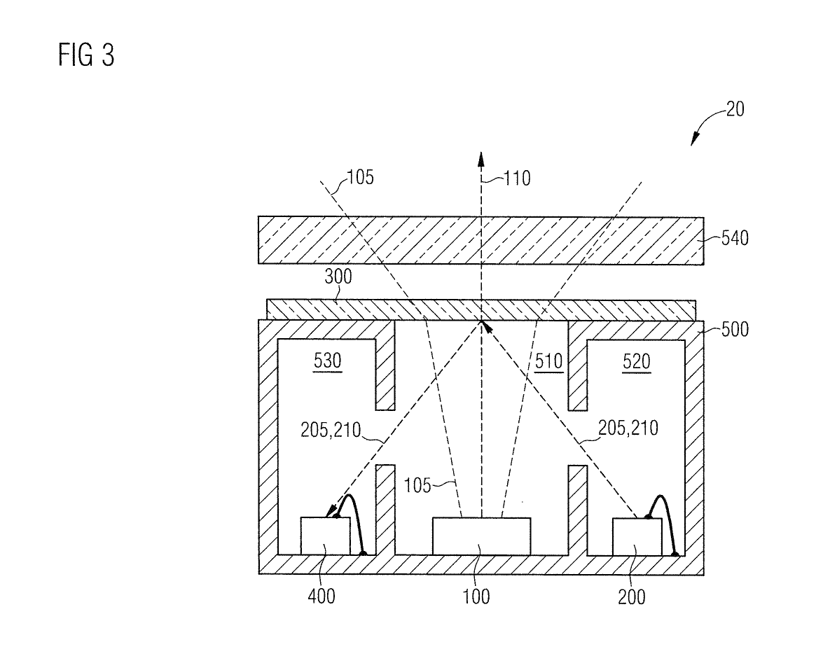

FIG. 3 shows a schematic sectional side view of an optoelectronic component 20 according to a second example. The optoelectronic component 20 of the second example has substantial correspondences to the optoelectronic component 10 of the first example described on the basis of FIGS. 1 and 2. Corresponding components are provided with the same reference signs in FIG. 3 as in FIGS. 1 and 2. Only the differences between the optoelectronic component 10 of the first example and the optoelectronic component 20 of the second example are described hereafter. Otherwise, the above description of the optoelectronic component 10 also applies accordingly to the optoelectronic component 20.

In the optoelectronic component 20, the first optoelectronic semiconductor chip 100 is designed as a vertically emitting laser chip. The first optoelectronic semiconductor chip 100 is arranged in the first chamber 510 of the housing 500 such that the first light path 110 of the useful light 105 emitted by the first optoelectronic semiconductor chip 100 extends directly to the optical element 300. The useful light 105 passes through the optical element 300 in the direction perpendicular to the plane of the optical element 300. Furthermore, the useful light 105 on the first light path 110 reaches the cover glass 540, which it also passes through in the perpendicular direction. A mirror element is not provided in the optoelectronic component 20.

The second light path 210 of the test light 205 emitted by the second optoelectronic semiconductor chip 200 extends in the optoelectronic component 20 of the second example from the second optoelectronic semiconductor chip 200 diagonally in the direction of the optical element 300 such that the test light 205 is incident on the optical element 300 at an angle deviating from 90° and from 0°. The test light 205 can be incident on the second light path 210 on the optical element 300, for example, at an angle of 45°. The angle at which the test light 205 is incident on the second light path 210 on the optical element 300 is dimensioned such that the test light 205 incident on the optical element 300 is reflected externally at the optical element 300. The test light 205 reflected at the optical element 300 reaches the light detector 400, where it is detected, on the further second light path 210.

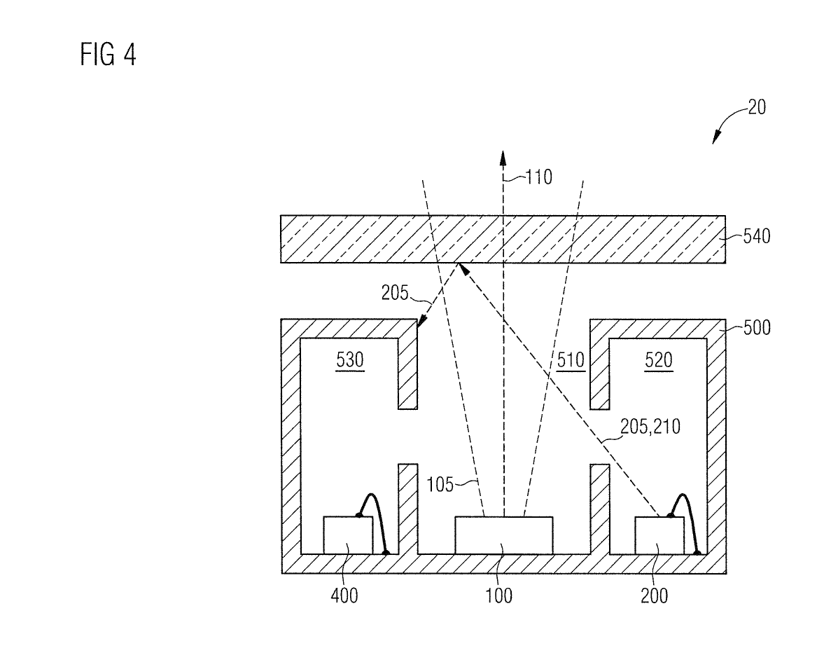

FIG. 4 shows a schematic sectional side view of the optoelectronic component 20 of the second example in a state in which the optical element 300 is absent. In the state of the optoelectronic component 20 shown in FIG. 4, useful light 105 emitted by the first optoelectronic semiconductor chip 100 could exit through the cover glass 540 of the housing 500 without previously having passed through the optical element 300. This could represent a risk to a user of the optoelectronic component 20. The first optoelectronic semiconductor chip 100 of the optoelectronic component 20 therefore cannot emit useful light 105 in the state shown in FIG. 4.

Test light 205 emitted by the second optoelectronic semiconductor chip 200 is emitted in the state of the optoelectronic component 20 shown in FIG. 4 by the second optoelectronic semiconductor chip 200 on the second light path 210 in the direction of the previously present optical element 300. Since the optical element 300 is absent in the state of the optoelectronic component 20 shown in FIG. 4, no reflection of the test light 205 takes place at the optical element 300. The second light path 210 is therefore interrupted in the state of the optoelectronic component 20 shown in FIG. 4 and no test light 205 or only a reduced amount of the test light 205 reaches the light detector 400 of the optoelectronic component 20. In this way, activation electronics of the optoelectronic component 20 are enabled to recognize the absence of the optical element 300.

The optoelectronic component 20 of the second example can be operated, in particular put into operation, according to the method described on the basis of the optoelectronic component 10 of the first example.

My components and methods are illustrated and described in greater detail on the basis of preferred examples. Nonetheless, this disclosure is not restricted to the disclosed examples. Rather, other variations can be derived therefrom by those skilled in the art, without leaving the scope of protection of the appended claims.

This application claim priority of DE 10 2016 104 946.8, the subject matter of which is incorporated herein by reference.

1-14. (canceled)

15. An optoelectronic component comprising:
a first optoelectronic semiconductor chip that emits useful light and extends in the optoelectronic component along a first light path,
an optical element arranged in the first light path,
a second optoelectronic semiconductor chip that emits test light and extends in the optoelectronic component along a second light path, wherein the optical element forms a part of the second light path, and
a light detector that detects test light that has passed through the second light path.

16. The optoelectronic component according to claim 15, wherein the optical element is a diffractive optical element.

17. The optoelectronic component according to claim 15, wherein the test light on the second light path is conducted through the optical element.

18. The optoelectronic component according to claim 17, wherein the second light path in the optical element extends perpendicularly to the first light path.

19. The optoelectronic component according to claim 15, wherein the test light on the second light path is deflected by the optical element.

20. The optoelectronic component according to claim 19, wherein the test light on the second light path is reflected externally at the optical element.

21. The optoelectronic component according to claim 19, wherein the test light on the second light path is reflected internally at the optical element.

22. The optoelectronic component according to claim 19, wherein the test light on the second light path is reflected multiple times at the optical element.

23. The optoelectronic component according to claim 15,
wherein the optoelectronic component comprises a mirror element, and
the useful light on the first light path is deflected at the mirror element.

24. The optoelectronic component according to claim 15, wherein the first optoelectronic semiconductor chip is a laser chip.

25. The optoelectronic component according to claim 15, wherein the second optoelectronic semiconductor chip is a light-emitting diode chip.

26. The optoelectronic component according to claim 15, wherein the light detector is a photodiode.

27. A method of operating an optoelectronic component comprising:
testing whether an established amount of test light emitted by a second optoelectronic semiconductor chip reaches a light detector along a second light path, of which an optical element forms a part; and
emitting useful light along a first light path in which the optical element is arranged by a first optoelectronic semiconductor chip if the testing was successful.

28. The method according to claim 27, wherein the testing comprises a first measurement of a signal supplied by the light detector, while the second optoelectronic semiconductor chip does not emit test light, and a second measurement of a signal supplied by the light detector, while the second optoelectronic semiconductor chip emits test light.
